(19) United States
(12) Patent Application Publication
(10) Pub. No.: US 2026/0065945 A1
(43) Pub. Date: Mar. 5, 2026

(54) MEMORY DEVICE HAVING PASS TRANSISTOR CIRCUIT

(71) Applicant: SK hynix Inc., Icheon-si (KR)

(72) Inventors: Chang Woo KANG, Icheon-si (KR); Go Hyun LEE, Icheon-si (KR)

(21) Appl. No.: 19/052,761

(22) Filed: Feb. 13, 2025

(30) Foreign Application Priority Data
Sep. 5, 2024 (KR) 10-2024-0120910

(51) Int. Cl. G11C 5/02; G11C 5/06

(52) U.S. Cl. CPC G11C 5/025; G11C 5/063

(57) ABSTRACT

A memory device including a substrate having a first active area and a second active area adjacent to each other in a first horizontal direction is disclosed. A first pass transistor is disposed on the substrate and has a first gate electrode crossing the first active area in the first horizontal direction, and a second pass transistor is disposed on the substrate and has a second gate electrode crossing the second active area in the first horizontal direction. The first active area has, in a planar view, a first recessed portion facing the second gate electrode on one side adjacent to the second active area.

### CROSS-REFERENCE TO RELATED APPLICATION

The present application claims priority under 35 U.S. C. § 119(a) to Korean patent application number 10-2024-0120910 filed in the Korean Intellectual Property Office on Sep. 5, 2024, which is incorporated herein by reference in its entirety.

### TECHNICAL FIELD

The embodiments of the present disclosure relate to a memory device having a pass transistor circuit.

### BACKGROUND

Memory devices may be classified into volatile memory devices and non-volatile memory devices. Non-volatile memory devices may include flash memory devices, and resistive memory devices such as resistive RAM (ReRAM), phase change RAM (PRAM), and magnetic RAM (MRAM). Memory devices may include a memory cell array and a pass transistor circuit, which transmits an operating voltage to word lines of the memory cell array.

### SUMMARY

Embodiments of the disclosure may provide a memory device having a pass transistor circuit.

Embodiments of the disclosure may provide a memory device including a substrate having a first active area and a second active area adjacent to each other in a first horizontal direction, a first pass transistor disposed on the substrate and having a first gate electrode crossing the first active area in the first horizontal direction, and a second pass transistor disposed on the substrate and having a second gate electrode crossing the second active area in the first horizontal direction, wherein the first active area has, in a planar view, a first recessed portion facing the second gate electrode on at a side adjacent to the second active area in the first horizontal direction.

Embodiments of the disclosure may provide a memory device including an active area provided on a substrate and having one side recessed in a first horizontal direction, and a pass transistor having a gate electrode disposed on the substrate and crossing a narrow portion of the active area common to the recessed portion, wherein the active area has a “ [symbol] ” shape including protrusions extending in the first horizontal direction from the recessed portion.

Embodiments of the disclosure may provide a memory device including a substrate having a first active area and a second active area adjacent to each other in a second horizontal direction perpendicular to a first horizontal direction, each having a recessed portion and a protrusion provided on one side, a first pass transistor disposed on the substrate and having a first gate electrode crossing a narrow portion of the first active area where the recessed portion is formed in the first horizontal direction, and a second pass transistor disposed on the substrate and having a second gate electrode crossing a narrow portion of the second active area where the recessed portion is formed in the first horizontal direction, wherein the protrusion of the first active area and the protrusion of the second active area extend in opposite directions.

According to embodiments of the present disclosure, it is possible to provide a memory device having a pass transistor circuit.

### BRIEF DESCRIPTION OF THE DRAWINGS

FIG. 1 is a block diagram of a memory device according to embodiments of the present disclosure.

FIG. 2 schematically illustrates a memory device according to embodiments of the present disclosure.

FIG. 3 illustrates first and second memory blocks, first and second pass transistor groups, a block select circuit, and a global row line decoder of FIG. 1.

FIG. 4 is a plan view illustrating pass transistors according to an embodiment of the present disclosure.

FIG. 5 is a cross-sectional view along line A-A′ of FIG. 4.

FIG. 6 and FIG. 7 are plan views illustrating portions of a pass transistor circuit according to embodiments of the present disclosure.

FIG. 8 is a plan view illustrating pass transistors according to an embodiment of the present disclosure.

FIG. 9 is a plan view illustrating pass transistors and contacts according to an embodiment of the present disclosure.

FIG. 10 is a plan view illustrating a portion of a pass transistor circuit according to an embodiment of the present disclosure.

FIG. 11 is a plan view illustrating pass transistors, contacts, and wirings according to an embodiment of the present disclosure.

FIG. 12 is a cross-sectional view along line B-B′ of FIG. 11.

FIG. 13 and FIG. 14 are plan views exemplarily illustrating a portion of a pass transistor circuit according to embodiments of the present disclosure.

### DETAILED DESCRIPTION

Hereinafter, various embodiments of the present disclosure will be described in detail with reference to accompanying drawings. The specific structural or functional descriptions of embodiments are provided as examples to explain the concepts disclosed herein. The embodiments or examples according to the concepts of the present disclosure may be implemented in various forms, and the scope of the present disclosure is not limited to the embodiments or examples described herein.

The same hatching shown throughout the drawings may indicate corresponding or identical areas in the drawings, and does not indicate materials associated with the corresponding areas.

When one element is described as being “connected” or “coupled” to another element, the elements may be directly connected or directly coupled, or may be connected or coupled through one or more intermediate elements between the elements. When two elements are described as being “directly connected” or “directly coupled,” one element is directly connected or directly coupled to the other element without any intermediate element between the two elements.

When one element is described as being disposed “over” or “under” another element, the elements may be in direct contact with each other, or an intermediate element may be disposed between the elements.

Terms such as “vertical,” “horizontal,” “upper,” “lower,”, “up”, “down”, “top,” “bottom,” “front,” “back,” “side,” “left and right,” “column,” “row,” “level,” and other relative spatial relationships or directions are used only for the purpose of ease of description or reference to the drawings, and are not limiting to any specific meaning. Other spatial relationships or directions not shown in the drawings or described in the specification are also possible within the scope of the present specification.

Terms such as “first” and “second” may be used to distinguish different elements and do not imply size, order, priority, quantity, or importance of the elements. For example, in some embodiments, a first element may be referred to as a second element, and in other embodiments, a second element may be referred to as a first element.

When an element included in embodiments in the present specification is described in the singular form, the element may be interpreted to include a plurality of elements performing the same or similar functions.

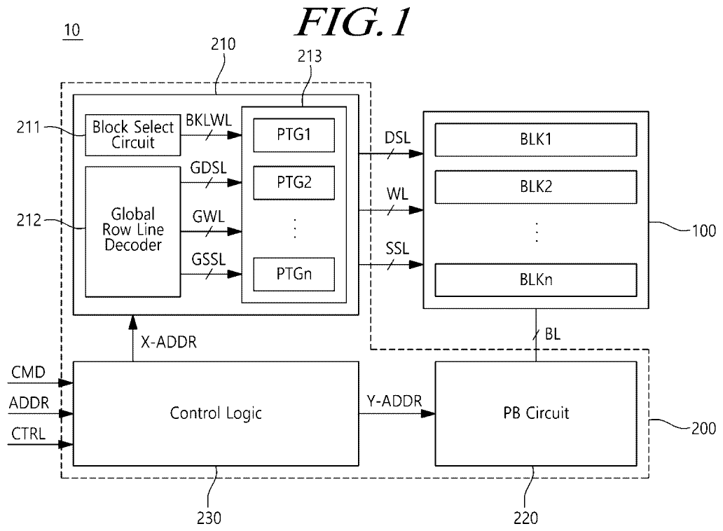

FIG. 1 is a block diagram of a memory device according to embodiments of the present disclosure.

Referring to FIG. 1, a memory device 10 may include a memory cell array 100 and a peripheral circuit 200. The peripheral circuit 200 may include a row decoder 210, a page buffer circuit 220, and control logic 230. Although not shown, the peripheral circuit 200 may further include a voltage generator, a data input/output circuit, a command decoder, an address decoder, and the like.

The memory cell array 100 may include a plurality of memory blocks BLK1-BLKn. Each of the memory blocks BLK1-BLKn may include a plurality of memory cells. The memory cell may be, for example, a flash memory cell. Hereinafter, memory cells are described as NAND flash memory cells, but the present disclosure is not limited thereto. The memory cells may also be resistive memory cells such as ReRAM, PRAM, or MRAM.

The memory cell array 100 may be connected to the row decoder 210 through row lines DSL, WL and SSL. The row lines SSL, WL and DSL may include source select lines SSL, word lines WL, and drain select lines DSL. The memory cell array 100 may be connected to the page buffer circuit 220 through a plurality of bit lines BL.

The row decoder 210 may include a block select circuit 211, a global row line decoder 212, and a pass transistor circuit 213.

The block select circuit 211 may be connected to the pass transistor circuit 213 via block select signal lines BLKWL. The block select circuit 211 may receive a row address X-ADDR from the control logic 230, and may output a block select signal for selecting one of a plurality of memory blocks BLK1-BLKn to one of the block select signal lines BLKWL in response to the received row address X-ADDR.

The global row line decoder 212 may be connected to the pass transistor circuit 213 via global row lines GDSL, GWL and GSSL. The global row lines GDSL, GWL and GSSL may include a global drain select line GDSL, global word lines GWL, and a global source select line GSSL. The global row line decoder 212 may receive operating voltages from a voltage generator (not shown), and output the operating voltages to the global drain select line GDSL, global word lines GWL, and the global source select line GSSL in response to a control signal received from the control logic 230.

The pass transistor circuit 213 may include a plurality of pass transistor groups PTG1-PTGn corresponding to a plurality of memory blocks BLK1-BLKn, respectively.

Each pass transistor group PTG may be connected to a corresponding memory block BLK through a drain select line DSL, word lines WL, and a source select line SSL. Each pass transistor group PTG may be connected to a global row line decoder 212 through a global drain select line GDSL, global word lines GWL, and a global source select line GSSL. The global drain select line GDSL, the global word lines GWL, and the global source select line GSSL may be commonly connected to a plurality of pass transistor groups PTG1-PTGn. That is, the plurality of pass transistor groups PTG1-PTGn may share a global drain select line GDSL, a plurality of global word lines GWL, and a global source select line GSSL.

One pass transistor group selected from among the pass transistor groups PTG1-PTGn, i.e., a pass transistor group receiving a block select signal from a block select circuit 211, may transfer operating voltages provided from a global row line decoder 212 to a corresponding memory block through a drain select line DSL, word lines WL, and a source select line SSL.

The page buffer circuit 220 may select some bit lines among the bit lines BL in response to a column address Y-ADDR. The page buffer circuit 220 may operate as a write driver or a sense amplifier depending on the operation mode.

The control logic 230 may control various operations within the memory device 10 in general. The control logic 230 may receive a command CMD, an address ADDR, and a control signal CTRL, and may generate various control signals for programming data in the memory cell array 100, reading data from the memory cell array 100, or erasing data stored in the memory cell array 100 based on the received command CMD, address ADDR, and control signal CTRL. The control logic 230 may output a row address X-ADDR and a column address Y-ADDR.

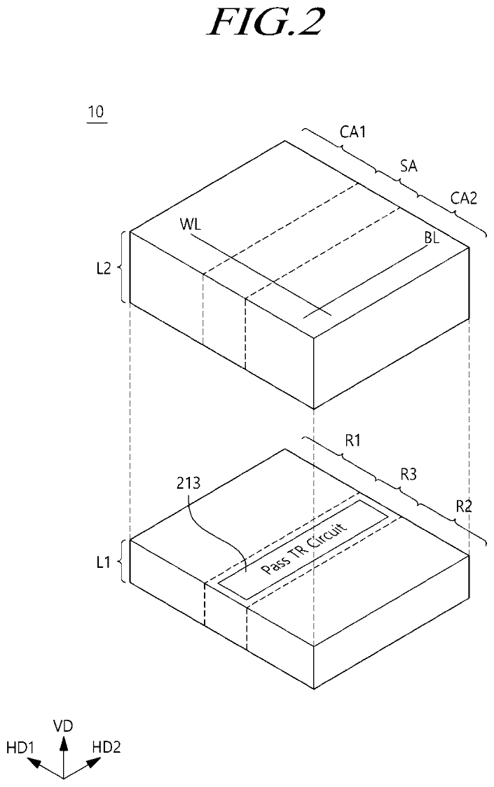

FIG. 2 schematically illustrates a memory device according to embodiments of the present disclosure.

Referring to FIG. 2, a memory device 10 may include a first semiconductor layer L1 and a second semiconductor layer L2. The first semiconductor layer L1 and the second semiconductor layer L2 may overlap with each other in a vertical direction VD. In FIG. 2, the first semiconductor layer L1 and the second semiconductor layer L2 are illustrated as being spaced apart from each other in the vertical direction VD, but this is for explanatory purposes, and it should be understood that an upper surface of the first semiconductor layer L1 and a lower surface of the second semiconductor layer L2 may be in contact with each other.

In one embodiment, a peripheral circuit (200 of FIG. 1) may be disposed on or in the first semiconductor layer L1, and a memory cell array (100 of FIG. 1) may be disposed on or in the second semiconductor layer L2.

In the second semiconductor layer L2, a plurality of word lines WL may extend in a first horizontal direction HD1, and a plurality of bit lines BL may extend in a second horizontal direction HD2. The second semiconductor layer L2 may include a first cell area CA1, a second cell area CA2, and a slimming area SA. The first cell area CA1 and the second cell area CA2 may be arranged in the first horizontal direction HD1, and the slimming area SA may be arranged between the first cell area CA1 and the second cell area CA2.

Although not illustrated, a plurality of word lines WL may be stacked in the vertical direction VD in the first and second cell areas CA1 and CA2 and the slimming area SA, thereby forming a stacked body. The word lines WL may be combined with semiconductor pillars penetrating the stack in a vertical direction VD to form three-dimensionally arranged memory cells. A plurality of word lines WL may be implemented in a step or stair shape in a slimming area SA.

The first semiconductor layer L1 may include a substrate, and a peripheral circuit (200 in FIG. 1) may be configured in the first semiconductor layer L1 by forming semiconductor elements such as transistors and a pattern for wiring the semiconductor elements on the substrate.

The first semiconductor layer L1 may include a first area R1 overlapping with a first cell area CA1 in the vertical direction VD, a second area R2 overlapping with a second cell area CA2 in the vertical direction VD, and a third area R3 overlapping with a slimming area SA in the vertical direction VD. In one embodiment, a pass transistor circuit 213 may be disposed in the third area R3, but embodiments are not limited thereto.

The first semiconductor layer L1 and the second semiconductor layer L2 may be fabricated on a single wafer. The first semiconductor layer L1 is formed first, the second semiconductor layer L2 may be built up on the first semiconductor layer L1. In this case, the memory device 10 may be defined as having a Peri-Under-Cell (PUC) structure.

In other embodiments, the first semiconductor layer L1 and the second semiconductor layer L2 may be fabricated on different wafers, and then bonded to each other by a bonding technique. In this case, the memory device 10 may be defined as having a Peri-Over-Cell (POC) structure.

The memory device 10 according to the present disclosure may be provided in a PUC structure or a POC structure. Although not shown, the memory cell array (100 of FIG. 1) and the peripheral circuit (200 of FIG. 1) may be planarly arranged on a single substrate.

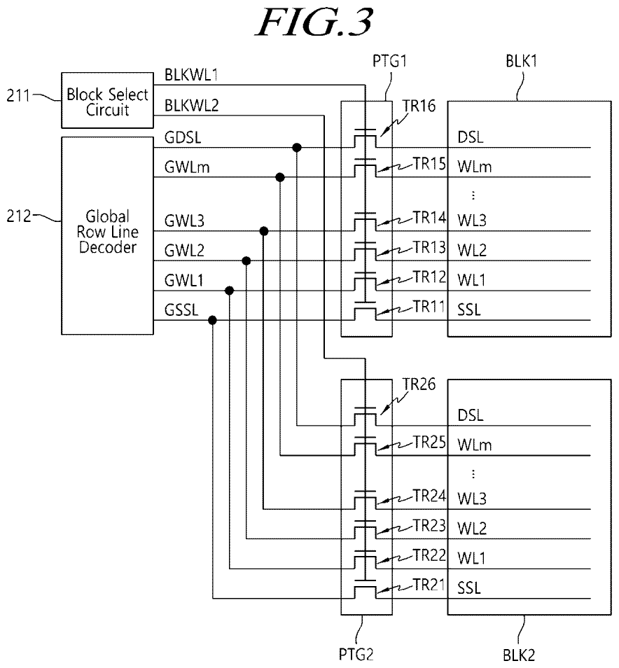

FIG. 3 illustrates first and second memory blocks, first and second pass transistor groups, a block select circuit, and a global row line decoder of FIG. 1.

Referring to FIG. 3, each of first and second memory blocks BLK1 and BLK2 may include a drain select line DSL, a plurality of word lines WL, and a source select line SSL.

A first pass transistor group PTG1 may include a plurality of first pass transistors TR11-TR16. A second pass transistor group PTG2 may include a plurality of second pass transistors TR21-TR26.

The gate electrodes of the first pass transistors TR11-TR16 may be commonly connected to a first block select signal line BLKWL1, and may be connected to a block select circuit 211 through the first block select signal line BLKWL1. The gate electrodes of the second pass transistors TR21-TR26 may be commonly connected to a second block select signal line BLKWL2, and may be connected to the block select circuit 211 through the second block select signal line BLKWL2.

The first pass transistor TR11 may be connected between the global source select line GSSL and the source select line SSL. The first pass transistors TR12-TR15 may be connected between the global word lines GWL1-GWLm and the word lines WL1-WLm, respectively. The first pass transistor TR16 may be connected between the global drain select line GDSL and the drain select line DSL. When an activated block select signal is provided through the first block select signal line BLKWL1, the first pass transistors TR11-TR16 are turned on, and thus, the operating voltages provided through the global source select line GSSL, the global word lines GWL1-GWLm, and the global drain select line GDSL may be transmitted to the first memory block BLK1 through the source select line SSL, the word lines WL1-WLm, and the drain select line DSL. The arrangement of the first pass transistor group PTG1 may also apply to the second pass transistor group PTG2, and therefore, a duplicate description will be omitted.

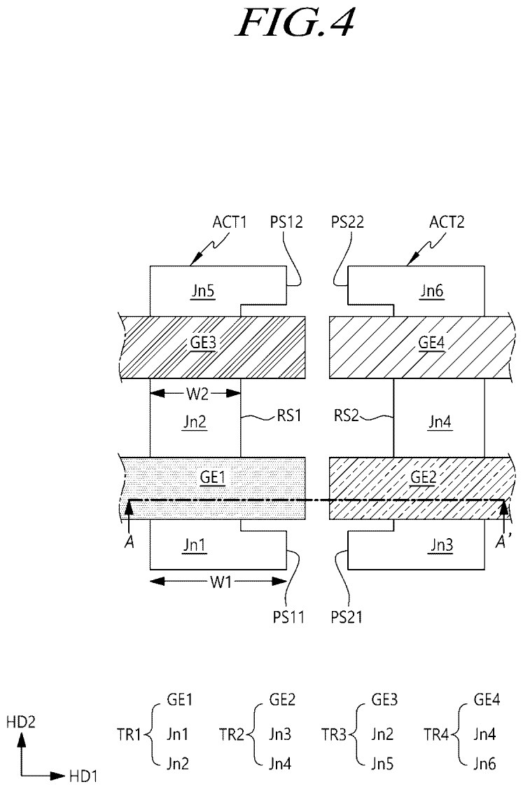

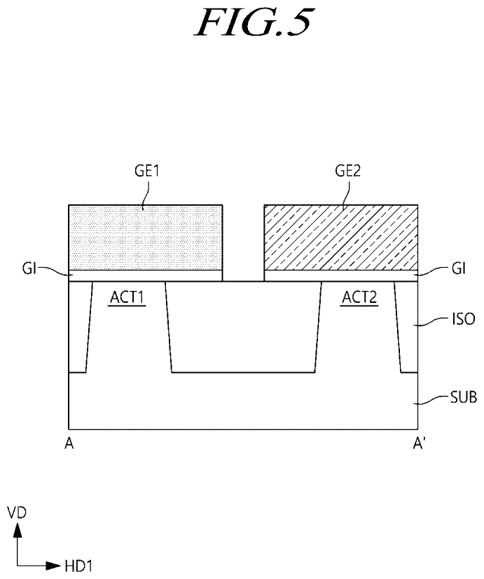

FIG. 4 is a plan view illustrating pass transistors according to an embodiment of the present disclosure, and FIG. 5 is a cross-sectional view along line A-A′ of FIG. 4.

Referring to FIG. 4, a first active area ACT1 and a second active area ACT2 may be provided on the substrate, which are adjacent to each other in the first horizontal direction HD1.

The first pass transistor TR1 may include a first gate electrode GE1, which crosses the first active area ACT1 in the first horizontal direction HD1. The second pass transistor TR2 may include a second gate electrode GE2, which crosses the second active area ACT2 in the first horizontal direction HD1. The first gate electrode GE1 and the second gate electrode GE2 may be disposed in a row along the first horizontal direction HD1.

The first active area ACT1 may have a first recessed portion RS1 on one side facing the second active area ACT2, and first and second protrusions PS11 and PS12 arranged in the second horizontal direction HD2 on both sides or ends of the first recessed portion RS1. For example, the first active area ACT1 may have a “ [symbol] ” shape. In this specification, a recessed portion may be referred to as a concave portion.

A width in the first horizontal direction HD1 of a portion of the first active area ACT1 including the first recessed portion RS1 may be smaller than a width in the first horizontal direction HD1 of a portion of the first active area ACT1 common to the first and second protrusions PS11 and PS12. For example, the width in the first horizontal direction HD1 of the portions of the first active area ACT1 with the first and second protrusions PS11 and PS12 is W1, and the width in the first horizontal direction HD1 of the portion of the first active area ACT1 with the first recessed portion RS1 is W2, and W2 may be smaller than W1.

The first gate electrode GE1 may cross, in the first horizontal direction HD1, a narrower portion of the first active area ACT1 where the first recessed portion RS1 is formed.

The second active area ACT2 may have a second recessed portion RS2 on one side facing the first active area ACT1, and third and fourth protrusions PS21 and PS22 arranged in the second horizontal direction HD2 on both sides or ends of the second recessed portion RS2. In an embodiment, the second active area ACT2 may have a reversed “ [symbol] ”shape.

A width of a portion of the second active area ACT2 in the first horizontal direction HD1 where the second recessed portion RS2 is formed may be smaller than a width of portions of the second active area ACT2 where the third and fourth protrusions PS21 and PS22 are formed in the first horizontal direction HD1. The second gate electrode GE2 may cross, in the first horizontal direction HD1, the narrower portion of the second active area ACT2 where the second recessed portion RS2 is formed.

A third gate electrode GE3 of a third pass transistor TR3 may cross a narrower portion of the first active area ACT1 in the first horizontal direction HD1. A fourth gate electrode GE4 of a fourth pass transistor TR4 may cross a narrower portion of the second active area ACT2 in the first horizontal direction HD1.

N-type or p-type impurities may be injected into the first active area ACT1 on both sides of the first gate electrode GE1 and the third gate electrode GE3, and into the second active area ACT2 on both sides of the second gate electrode GE2 and the fourth gate electrode GE4, so that junction areas Jn1-Jn6 may be formed.

The first pass transistor TR1 may include the first gate electrode GE1, and first and second junction areas Jn1 and Jn2 on both sides of the first gate electrode GE1. The second pass transistor TR2 may include the second gate electrode GE2, and third and fourth junction areas Jn3 and Jn4 on both sides of the second gate electrode GE2. The third pass transistor TR3 may include the third gate electrode GE3, and second and fifth junction areas Jn2 and Jn5 on both sides of the third gate electrode GE3. The fourth pass transistor TR4 may include a fourth gate electrode GE4, and fourth and sixth junction areas Jn4 and Jn6 on both sides of the fourth gate electrode GE4.

The first pass transistor TR1 and the third pass transistor TR3 may be configured in the first active area ACT1, and may share the second junction area Jn2. The second pass transistor TR2 and the fourth pass transistor TR4 may be configured in the second active area ACT2 and, may share the fourth junction area Jn4. Global row lines may be connected to the second junction area Jn2 and the fourth junction area Jn4, respectively.

The first pass transistor TR1 and the second pass transistor TR2 may be connected to different memory blocks. That is, the first pass transistor TR1 and the second pass transistor TR2 may be included in different pass transistor groups. For example, the first pass transistor TR1 may be included in a first pass transistor group, and the second pass transistor TR2 may be included in a second pass transistor group. In this case, the first gate electrode GE1 may be connected to a first block select signal line, the first junction area Jn1 may be connected to a row line of a first memory block, the second gate electrode GE2 may be connected to a second block select signal line, and the third junction area Jn3 may be connected to a row line of a second memory block.

The third pass transistor TR3 and the fourth pass transistor TR4 may be connected to different memory blocks. That is, the third pass transistor TR3 and the fourth pass transistor TR4 may be included in different pass transistor groups. For example, the third pass transistor TR3 may be included in a third pass transistor group, and the fourth pass transistor TR4 may be included in a fourth pass transistor group. In this case, the third gate electrode GE3 may be connected to a third block select signal line, the fifth junction area Jn5 may be connected to a row line of a third memory block, the fourth gate electrode GE4 may be connected to a fourth block select signal line, and the sixth junction area Jn6 may be connected to a row line of a fourth memory block.

A first protrusion PS11 of the first active area ACT1 may be spaced apart from the first gate electrode GE1 in the second horizontal direction HD2, and a second protrusion PS12 of the first active area ACT1 may be spaced apart from the third gate electrode GE3 in the second horizontal direction HD2. A first junction area Jn1 may be formed in the first protrusion PS11 of the first active area ACT1, and a fifth junction area Jn5 may be formed in the second protrusion PS12 of the first active area ACT1.

A third protrusion PS21 of the second active area ACT2 may be spaced apart from the second gate electrode GE2 in the second horizontal direction HD2, and a fourth protrusion PS22 of the second active area ACT2 may be spaced apart from the fourth gate electrode GE4 in the second horizontal direction HD2. A third junction area Jn3 may be formed in the third protrusion PS21 of the second active area ACT2, and a sixth junction area Jn6 may be formed in the fourth protrusion PS22 of the second active area ACT2.

Referring to FIGS. 4 and 5, the first active area ACT1 and the second active area ACT2 may be defined by a device isolation film ISO provided on a substrate SUB. A device isolation trench may be formed in the substrate SUB, and the device isolation film ISO may fill the device isolation trench. The device isolation film ISO may surround the first active area ACT1 and the second active area ACT2. The first active area ACT1 and the second active area ACT2 may be separated from each other by the device isolation film ISO.

The first and second gate electrodes GE1 and GE2 may be arranged on a substrate SUB, on which the device isolation film ISO is formed. A gate insulating layer GI may be provided under the first and second gate electrodes GE1 and GE2 to separate the substrate SUB from each of the first and second gate electrodes GE1 and GE2.

A part of the first gate electrode GE1 may overlap with the first active area ACT1 in the vertical direction VD. A part of the second gate electrode GE2 may overlap with the second active area ACT2 in the vertical direction VD.

As described above, since the first gate electrode GE1 and the second gate electrode GE2 are connected to different memory blocks, when high voltage is applied to one of the first gate electrode GE1 or the second gate electrode GE2, a ground voltage may be applied to the other. For example, if the second memory block is selected, then a high voltage may be applied to the second gate electrode GE2 and a ground voltage may be applied to the first gate electrode GE1.

According to the present disclosure, since a portion of the first recessed portion RS1 that faces the second gate electrode GE2 is formed in the first active area ACT1, the gap or distances in the first horizontal direction HD1 between the first active area ACT1 under the first gate electrode GE1 and the second gate electrode GE2 may be larger compared to a case in with active areas are not formed with recessed portions RS1 or RS2. Accordingly, the influence of a higher voltage, which is applied to the second gate electrode GE2, on the first active area ACT1 under the first gate electrode GE1 may be reduced, so that it is possible to reduce or mitigate the generation of leakage current when a channel is formed in the first active area ACT1 under the first gate electrode GE1 due to the high voltage applied to the second gate electrode GE2.

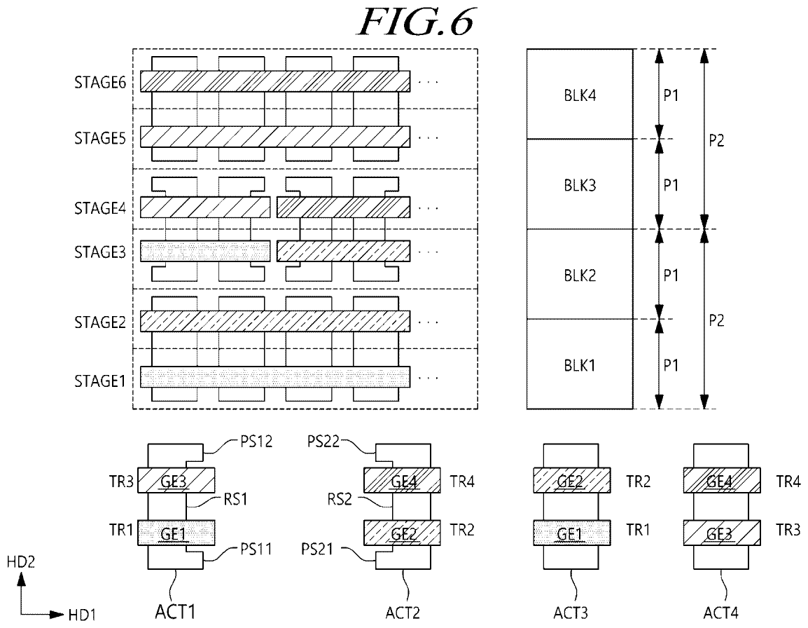

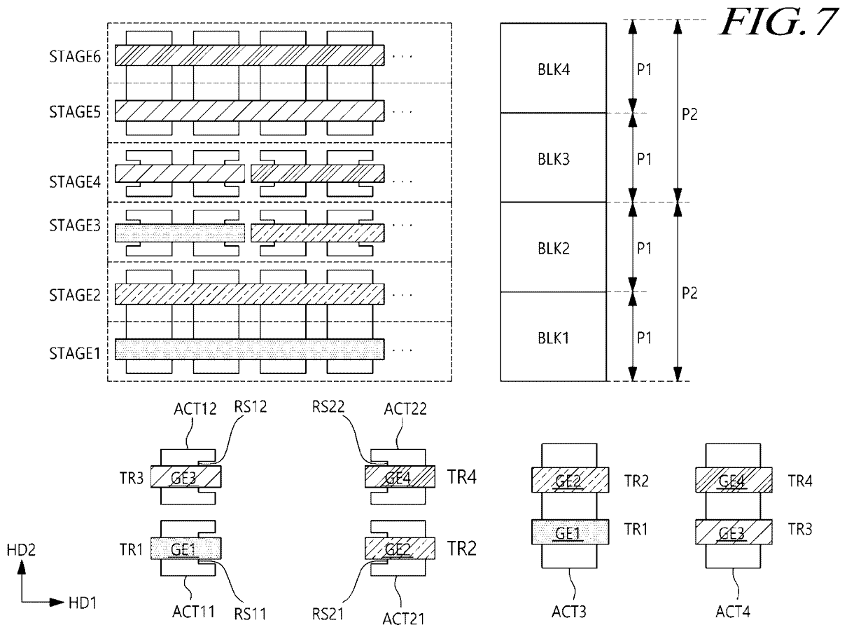

FIGS. 6 and 7 are plan views illustrating portions of a pass transistor circuit according to embodiments of the present disclosure. FIGS. 6 and 7 illustrate first, second, third, and fourth pass transistor groups corresponding to first, second, third, and fourth memory blocks BLK1, BLK2, BLK3 and BLK4 among pass transistor groups included in a pass transistor circuit.

Referring to FIG. 6, first, second, third and fourth memory blocks BLK1, BLK2, BLK3 and BLK4 may be arranged in a row along the second horizontal direction HD2. The dimension of each of first, second, third and fourth memory blocks BLK1, BLK2, BLK3 and BLK4 in the second horizontal direction HD2 may be P1. P1 may be defined as a single block pitch. In the second horizontal direction HD2, dimension of the first and second memory blocks BLK1 and BLK2, may be P2. P2 may be defined as two block pitch. Similarly, the dimension in the second horizontal direction HD2 of a combination of two adjacent third and fourth memory blocks BLK3 and BLK4 may be two block pitch P2.

The first and second pass transistors TR1 and TR2 of the first and second pass transistor groups may be arranged in odd number of stages. For example, the first and second pass transistors TR1 and TR2 may be arranged in the first, second and third stages STAGE1, STAGE2 and STAGE3.

For example, in FIGS. 6 and 7, some of the first pass transistors TR1 of the first pass transistor group may be disposed in the first stage STAGE1, and the rest may be disposed in the third stage STAGE3. Some of the second pass transistors TR2 of the second pass transistor group may be disposed in the second stage STAGE2, and the rest may be disposed in the third stage STAGE3. The first pass transistor group and the second pass transistor group may share the third stage STAGE3.

The third and fourth pass transistors TR3 and TR4 of the third and fourth pass transistor groups may be disposed in odd number of stages. For example, the third and fourth pass transistors TR3 and TR4 may be disposed in the fourth, fifth and sixth stages STAGE4, STAGE5 and STAGE6.

Some of the third pass transistors TR3 of the third pass transistor group may be disposed in the fifth stage STAGE5, and the rest may be disposed in the fourth stage STAGE4. Some of the fourth pass transistors TR4 of the fourth pass transistor group may be disposed in the sixth stage STAGE6, and the rest may be disposed in the fourth stage STAGE4. The third pass transistor group and the fourth pass transistor group may share the fourth stage STAGE4.

The dimension of the second horizontal direction HD2 of three consecutive stages may be equal to P2, i.e., two block pitch. In this case, the pass transistor circuit may be defined as having a 3-stage-2-block structure.

In an embodiment, referring to FIG. 6, the first pass transistors TR1 of the third stage STAGE3 and the third pass transistors TR3 of the fourth stage STAGE4 may share one first active area ACT1 while being arranged in a row in the second horizontal direction HD2. The second pass transistors TR2 of the third stage STAGE3 and the fourth pass transistors TR4 of the fourth stage STAGE4 may share one second active area ACT2 while being arranged in a row in the second horizontal direction HD2.

In a planar view, the first active area ACT1 may have a first recessed portion RS1 facing the second gate electrode GE2 and the fourth gate electrode GE4 on a side adjacent to the second active area ACT2. On that same side, first active area ACT1 may have first and second protrusions PS11 and PS12 in the second horizontal direction HD2 on both sides of the first recessed portion RS1. In a planar view, the second active area ACT2 may have a second recessed portion RS2 facing the first gate electrode GE1 and the third gate electrode GE3 on a side adjacent to the first active area ACT1. On that same side, second active area ACT2 may have third and fourth protrusions PS21 and PS22 in the second horizontal direction HD2 on both sides of the second recessed portion RS2.

One of the first pass transistors TR1 of the first stage STAGE1 and one of the second pass transistors TR2 of the second stage STAGE2 may be arranged in a row extending in the second horizontal direction HD2 and share a third active area ACT3. Similarly, one of the third pass transistors TR3 of the fifth stage STAGE5 and one of the fourth pass transistors TR4 of the sixth stage STAGE6 may be arranged in a row extending in the second horizontal direction HD2 and share a fourth active area ACT4. The third active area ACT3 and the fourth active area ACT4 may each have a rectangular structure.

Although not illustrated, the first, second, third and fourth memory blocks BLK1, BLK2, BLK3 and BLK4 may be disposed in a first semiconductor layer L1 of FIG. 2. The first, second and third stages STAGE1, STAGE2 and STAGE3 may be arranged to overlap with step areas of word lines of the first and second memory blocks in a second semiconductor layer L2 of FIG. 2 in the vertical direction VD. The fourth, fifth and sixth stages STAGE4, STAGE5 and STAGE6 may be disposed to overlap with step areas of word lines of the third and fourth memory blocks in the second semiconductor layer L2 of FIG. 2 in the vertical direction VD.

Referring to FIG. 7, the first pass transistor TR1 of the third stage STAGE3 and the third pass transistor TR3 of the fourth stage STAGE4 do not share an active area. The second pass transistor TR2 of the third stage STAGE3 and the fourth pass transistor TR4 of the fourth stage STAGE4 do not share an active area.

In the third stage STAGE3, the first gate electrode GE1 of the first pass transistor TR1 may cross a first individual active area ACT11 in the first horizontal direction HD1. In the third stage STAGE3, the second gate electrode GE2 of the second pass transistor TR2 may cross a second individual active area ACT21 in the first horizontal direction HD1.

In the fourth stage STAGE4, the third gate electrode GE3 of the third pass transistor TR3 may cross a third individual active area ACT12 in the first horizontal direction HD1. The fourth gate electrode GE4 of the fourth pass transistor TR4 of the fourth stage STAGE4 may cross a fourth individual active area ACT22 in the first horizontal direction HD1.

The first individual active area ACT11 may have a recessed portion RS11 facing the second gate electrode GE2 on a side adjacent to the second individual active area ACT21. The second individual active area ACT21 may have a recessed portion RS21 facing the first gate electrode GE1 on a side adjacent to the first individual active area ACT11.

The third individual active area ACT12 may have a recessed portion RS12 facing the fourth gate electrode GE4 on a side adjacent to the fourth individual active area ACT22. The fourth individual active area ACT22 may have a recessed portion RS22 facing the third gate electrode GE3 on a side adjacent to the third individual active area ACT12.

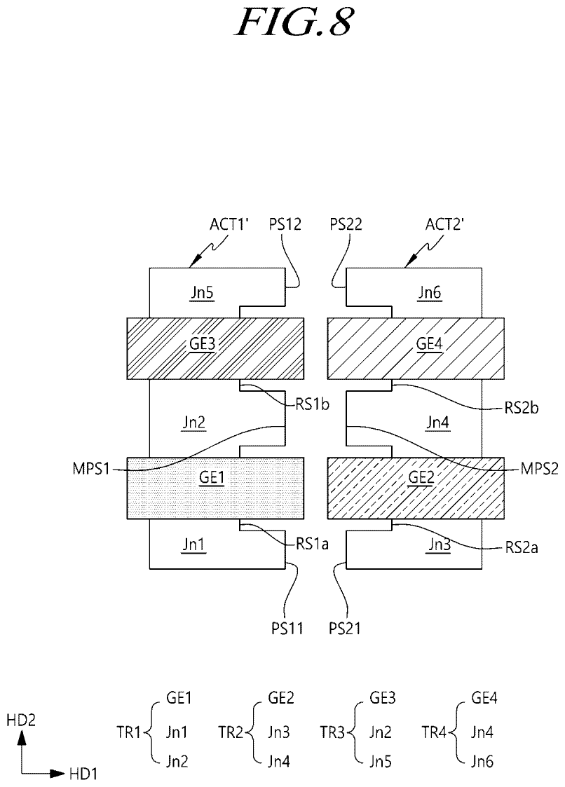

FIG. 8 is a plan view illustrating pass transistors according to an embodiment of the present disclosure.

Referring to FIG. 8, a first active area ACT1′ may have a first recessed portion RS1a and a second recessed portion RS1b, respectively facing a second gate electrode GE2 and a fourth gate electrode GE4 on a side adjacent to a second active area ACT2′. The first active area ACT1′ may have a first middle protrusion MPS1, protruding in the first horizontal direction HD1, disposed between the first recessed portion RS1a and the second recessed portion RS1b in the second horizontal direction HD2 to separate the first recessed portion RS1a and the second recessed portion RS1b. In an embodiment, the first active area ACT1′ may have an “E”shape.

The second active area ACT2′ may have a third recessed portion RS2a and a fourth recessed portion RS2b, respectively facing the first gate electrode GE1 and the third gate electrode GE3 on a side adjacent to the first active area ACT1′, The second active area ACT2′ may have a second middle protrusion MPS2, protruding in the first horizontal direction HD1, disposed between the third recessed portion RS2a and the fourth recessed portion RS2b to separate the third recessed portion RS2a and the fourth recessed portion RS2b. In an embodiment, the second active area ACT2′ may have a reverse “E” shape.

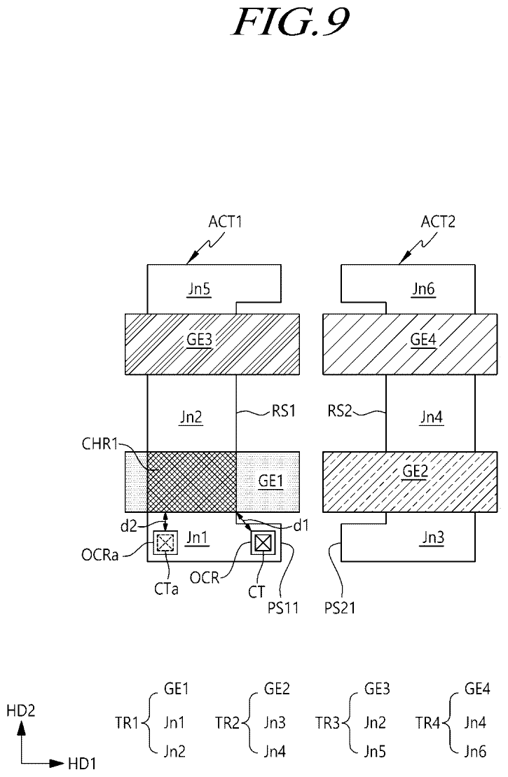

FIG. 9 is a plan view illustrating pass transistors and contacts according to an embodiment of the present disclosure.

Referring to FIG. 9, a contact CT may be disposed on a first protrusion PS11 of a first junction area Jn1. The contact CT may be connected to the first protrusion PS11, and may extend vertically from the first protrusion PS11. The contact CT may be spaced apart from a portion CHR1 (hereinafter referred to as “first active area under the first gate electrode”) of the first active area ACT1, which vertically overlaps with the first gate electrode GE1. From a plan view, the contact CT may be spaced apart from the portion CHR1 in a diagonal direction (e.g., extending in the direction of a distance d1) intersecting the first horizontal direction HD1 and the second horizontal direction HD2.

An ohmic contact region OCR may be formed on the first protrusion PS11 of the first junction area Jn1 under the contact CT. The ohmic contact region OCR may be formed to facilitate electrical connection between the contact CT and the first junction area Jn1, and may be doped with a higher concentration of n-type or p-type impurities than the first junction area Jn1. The ohmic contact region OCR and the first active area under the first gate electrode CHR1 may be spaced apart from each other in the diagonal direction, and the gap between the ohmic contact region OCR and the first active area under the first gate electrode CHR1 may be the distance d1.

In comparative cases, a contact CTa may be arranged in a portion of the first junction area Jn1 other than the first protrusion PS11, as indicated by a dotted line in FIG. 9. Here, the contact CTa may be spaced apart from the first active area under the first gate electrode CHR1 in the second horizontal direction HD2, and the gap between an ohmic contact region OCRa under the contact CTa and the first active area under the first gate electrode CHR1 may be a distance d2, which is less than d1. If the gap between the ohmic contact region OCRa and the first active area under the first gate electrode CHR1 is smaller, a depletion layer may be formed with a wide width between the first active area under the first gate electrode CHR1 and the first junction area Jn1 due to the influence of the highly doped ohmic contact region OCRa so that the channel length shortens. Thus, in comparative examples the threshold voltage of the first pass transistor TR1 may be lowered due to the reduced channel length, which may cause leakage current to occur.

In contrast, according to an embodiment of the present disclosure, the contact CT is disposed on the first protrusion PS11 of the first active area ACT1, therefore the gap between the contact CT and the first active area under the first gate electrode CHR1 is comparatively larger. The gap between the ohmic contact region OCR and the first active area under the first gate electrode CHR1 may be increased so that leakage current due to the influence of the ohmic contact region OCR may be suppressed in the first pass transistor TR1.

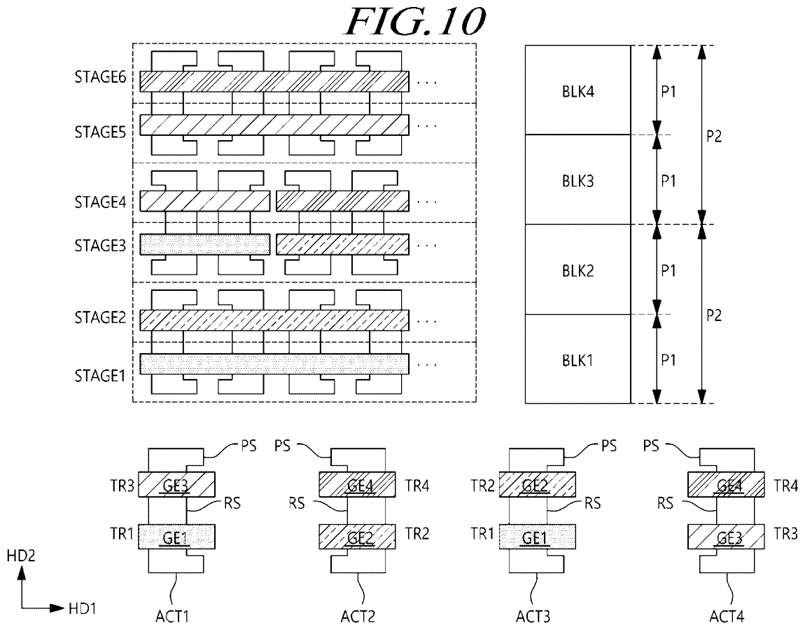

FIG. 10 is a plan view illustrating a portion of a pass transistor circuit according to an embodiment of the present disclosure.

Referring to FIG. 10, each of first, second, third and fourth active areas ACT1, ACT2 ACT3 and ACT4 may have recessed portions RS that face each other in the first horizontal direction HD1. Each of first, second, third and fourth active areas ACT1, ACT2 ACT3 and ACT4 may have protrusions PS on both sides of the recessed portion RS, which protrude the first horizontal direction HD1 and are arranges in the second horizontal direction HD2. In an embodiment, each of the first and second active areas ACT1 and ACT2 may have a “ [symbol] ” shape that mirror each other in the first horizontal direction HD1 and each of the third and fourth active areas ACT3 and ACT4 may have a “ [symbol] ” shape that mirror each other in the first horizontal direction HD1.

Each of the first, second, third and fourth active areas ACT1, ACT2, ACT3 and ACT4 may have a structure that is symmetrical on the left and right with respect to adjacent active areas in the second horizontal direction HD2. For example, the recessed portion RS and the protrusions PS of the first active area ACT1 may be configured on the right side of the first active area ACT1, and the recessed portion RS and the protrusions PS of the third active area ACT3 adjacent to the first active area ACT1 in the second horizontal direction HD2 may be configured on the left side of the third active area ACT3. Thus, the protrusions PS of the active areas adjacent to each other in the second horizontal direction HD2 may protrude in opposite directions. As a result, the protrusions PS of the active areas adjacent to each other in the second horizontal direction HD2, such as for example ACT1 and ACT3 in FIG. 10, may not overlap with each other in the second horizontal direction HD.

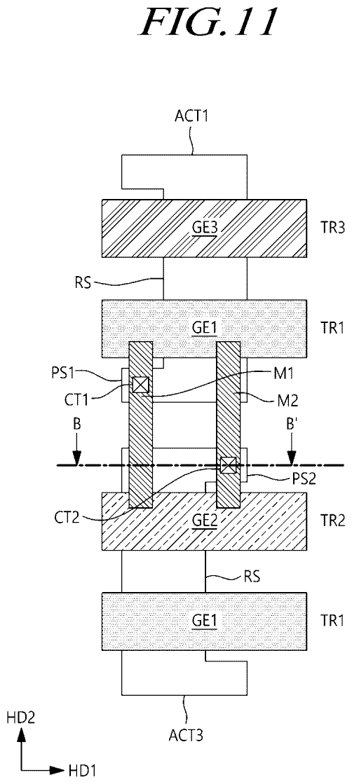

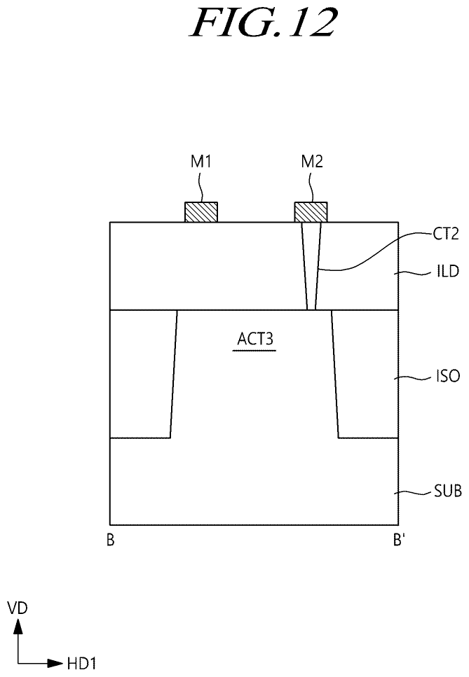

FIG. 11 is a plan view illustrating pass transistors, contacts, and wirings according to an embodiment of the present disclosure, and FIG. 12 is a cross-sectional view along line B-B′ of FIG. 11.

Referring to FIG. 11 and FIG. 12, an interlayer insulating layer ILD may be provided on a substrate SUB to cover pass transistors TR1, TR2 and TR3.

First and second wirings M1 and M2 may be disposed on the interlayer insulating layer ILD. The first wiring M1 and the second wiring M2 may be disposed on the same layer.

In a planar view, the first wiring M1 may extend in the second horizontal direction HD2 and intersect with the protrusion PS1 of the first active area ACT1. A first contact CT1 may be disposed in an area where the protrusion PS1 of the first active area ACT1 and the first wiring M1 intersect. The first contact CT1 may penetrate the interlayer insulating film ILD1 in the vertical direction VD between the protrusion PS1 of the first active area ACT1 and the first wiring M1, and electrically connect the first active area ACT1 and the first wiring M1.

In a planar view, the second wiring M2 may extend in the second horizontal direction HD2, and intersect with the protrusion PS2 of the third active area ACT3. A second contact CT2 may be disposed in the area where the protrusion PS2 of the third active area ACT3 and the second wiring M2 intersect. The second contact CT2 may penetrate the interlayer insulating film ILD2 in the vertical direction VD between the protrusion PS2 of the third active area ACT3 and the second wiring M2, and can electrically connect the third active area ACT3 and the second wiring M2.

In comparative examples, if the protrusion of the first active area and the protrusion of the third active area overlap with each other in the second horizontal direction, then the first wiring and the second wiring may be disposed in a line along the second horizontal direction. In this case, it is difficult to manage wiring spacing, so the first wiring and the second wiring may need to be arranged in different wiring layers.

According to the embodiments of the present disclosure however, the protrusions PS1 and PS2 of the first active area ACT1 and the third active area ACT3 adjacent to each other in the second horizontal direction HD2 do not overlap with each other in the second horizontal direction HD2, and the first wiring M1 and the second wiring M2 may be arranged parallel to each other, so that the first wiring M1 and the second wiring M2 can be arranged in a single wiring layer as illustrated in FIG. 12.

The embodiments described above with reference to FIGS. 3 to 12 illustrate two pass transistor groups sharing one stage, but other embodiments are not limited thereto. For example, in some embodiments, only one pass transistor group may be disposed in one stage.

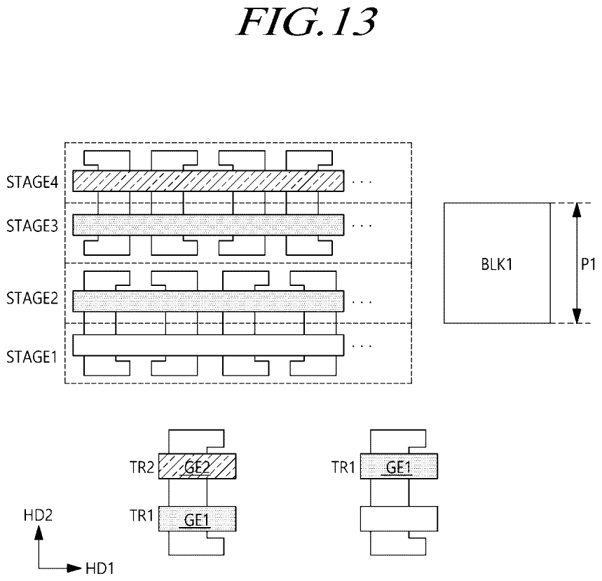

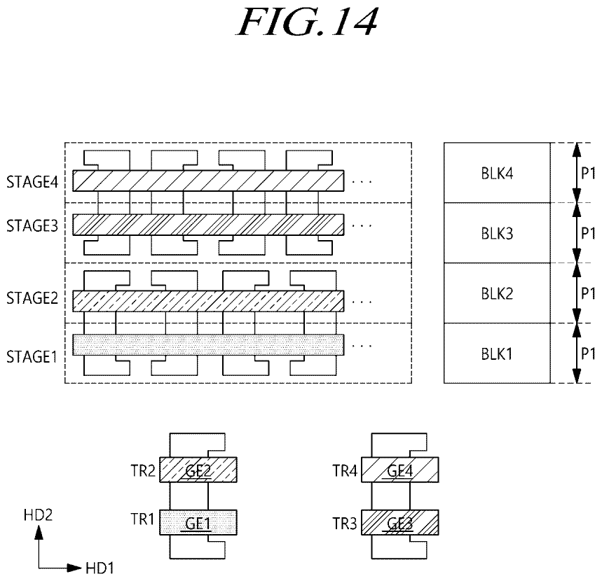

FIGS. 13 and 14 are plan views exemplarily illustrating a portion of a pass transistor circuit according to embodiments of the present disclosure.

Referring to FIG. 13, pass transistors of one pass transistor group may be disposed in two stages. For example, first pass transistors TR1 of a first pass transistor group may be disposed in a second stage STAGE2 and a third stage STAGE3. The dimension in the second horizontal direction HD2 of two stages may be the same as single block pitch P1. A pass transistor circuit accordingly may have a 2-stage-1-block structure.

Referring to FIG. 14, the pass transistors of each pass transistor group may be disposed in its own stage. For example, first pass transistors TR1 of a first pass transistor group may be disposed in a first stage STAGE1, second pass transistors TR2 of a second pass transistor group may be disposed in a second stage STAGE2, third pass transistors TR3 of a third pass transistor group may be disposed in a third stage STAGE3, and fourth pass transistors TR4 of a fourth pass transistor group may be disposed in a fourth stage STAGE4.

The dimension of one stage in the second horizontal direction HD2 may be equal to single block pitch P1. The pass transistor circuit accordingly have a 1-stage-1-block structure.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical ideas of this disclosure but to explain the technical ideas of this disclosure, the scope of the technical ideas of this disclosure is not limited by these embodiments. The protection scope of this disclosure should be interpreted by the claims below, and all technical ideas within the equivalent scope should be interpreted as being included in the scope of the rights of this disclosure.

What is claimed is:

1. A memory device comprising:
a substrate having a first active area and a second active area adjacent to each other in a first horizontal direction;
a first pass transistor disposed on the substrate and having a first gate electrode crossing the first active area in the first horizontal direction; and
a second pass transistor disposed on the substrate and having a second gate electrode crossing the second active area in the first horizontal direction,
wherein the first active area has, in a planar view, a first recessed portion facing the second gate electrode on at a side adjacent to the second active area in the first horizontal direction.

2. The memory device of claim 1, wherein the first pass transistor and the second pass transistor are connected to different memory blocks.

3. The memory device of claim 1, wherein the first recessed portion is a narrower portion, in the first horizontal direction, of the first active area and the first gate electrode crosses the narrower portion of the first active area in the first horizontal direction.

4. The memory device of claim 1, wherein the first gate electrode and the second gate electrode are arranged in a row along the first horizontal direction.

5. The memory device of claim 1, further comprising:
a third pass transistor disposed on the substrate and having a third gate electrode crossing the first active area in the first horizontal direction; and
a fourth pass transistor disposed on the substrate and having a fourth gate electrode crossing the second active area in the first horizontal direction.

6. The memory device of claim 5, wherein the third gate electrode crosses a narrower portion of the first active area in the first horizontal direction.

7. The memory device of claim 5, wherein the first active area further includes, in a planar view, a second recessed portion and a protrusion at the side adjacent to the second active area,
wherein the second recessed portion faces the fourth gate electrode in the first horizontal direction, and the protrusion extends in the first horizontal direction the first recessed portion and the second recessed portion.

8. The memory device of claim 7, wherein the first gate electrode crosses a first narrower portion of the first active area where the first recessed portion is formed,
wherein the third gate electrode crosses a second narrower portion of the first active area where the second recessed portion is formed.

9. The memory device of claim 1, wherein the second active area has a second recessed portion facing the first gate electrode.

10. The memory device of claim 1, further comprising:
a first memory block connected to the first pass transistor; and
a second memory block connected to the second pass transistor,
wherein the first pass transistor and the second pass transistor are included in a first semiconductor layer, and the first memory block and the second memory block are included in a second semiconductor layer,
wherein the first semiconductor layer vertically overlaps the second semiconductor layer.

11. The memory device of claim 1, further comprising:
a first memory block connected to the first pass transistor; and
a second memory block connected to the second pass transistor,
wherein the first pass transistor and the second pass transistor are included in a first wafer, and the first memory block and the second memory block are included in a second wafer bonded to the first wafer.

12. A memory device comprising:
an active area provided on a substrate and having one side recessed in a first horizontal direction; and
a pass transistor having a gate electrode disposed on the substrate and crossing a narrow portion of the active area common to a recessed portion,
wherein the active area has a “ [symbol] ” shape including protrusions extending in the first horizontal direction from the recessed portion.

13. The memory device of claim 12, further comprising a contact connected to one of the protrusions.

14. The memory device of claim 13, wherein a portion of the active area vertically overlapping with the gate electrode and the contact are spaced apart from each other in a diagonal direction, which intersects the first horizontal direction and a second horizontal direction perpendicular to the first horizontal direction in a planar view.

15. The memory device of claim 13, further comprising an ohmic contact region provided on the one of the protrusions of the active area,
wherein the contact is connected to the ohmic contact region.

16. A memory device comprising:
a substrate having a first active area and a second active area adjacent to each other in a second horizontal direction perpendicular to a first horizontal direction, each having a recessed portion and a protrusion provided on one side;
a first pass transistor disposed on the substrate, having a first gate electrode extending in the first horizontal direction, and crossing a narrow portion of the first active area where the recessed portion is formed; and
a second pass transistor disposed on the substrate, having a second gate electrode extending in the first horizontal direction, and crossing a narrow portion of the second active area where the recessed portion is formed,
wherein the protrusion of the first active area and the protrusion of the second active area extend in opposite directions.

17. The memory device of claim 16, wherein the protrusion of the first active area and the protrusion of the second active area do not overlap with each other in the second horizontal direction.

18. The memory device of claim 16, further comprising:
a first contact connected to the protrusion of the first active area;
a second contact connected to the protrusion of the second active area;
a first wiring connected to the first contact; and
a second wiring connected to the second contact,
wherein the first wiring and the second wiring are arranged parallel to each other.

19. The memory device of claim 18, wherein the first wiring and the second wiring extend in the second horizontal direction.

20. The memory device of claim 18, wherein the first wiring and the second wiring are disposed in a same layer.
